(19) United States
(12) Patent Application Publication
(10) Pub. No.: US 2013/0081671 A1
(43) Pub. Date: Apr. 4, 2013

(54) Sun Tracking Foldable Solar Umbrellas for Electricity and Hot Water Generation

(71) Applicants: Joseph Y. Hui, Fountain Hills, AZ (US); Joseph W. Bostaph, Chandler, AZ (US); Daniel A. Zindel, Mesa, AZ (US); Forest Blair, Centerville, UT (US)

(72) Inventors: Joseph Y. Hui, Fountain Hills, AZ (US); Joseph W. Bostaph, Chandler, AZ (US); Daniel A. Zindel, Mesa, AZ (US); Forest Blair, Centerville, UT (US)

(21) Appl. No.: 13/249,110

(22) Filed: Sep. 29, 2011

(51) Int. Cl. H01L 31/058; H01L 31/06; H01L 31/0232

(52) U.S. Cl. 136/248; 136/259; 136/255

(57) ABSTRACT

A lightweight, small volume and highly portable solar electricity collector. The collector may be configured as a solar umbrella made up of components that are able to fold up into a small package and fit inside of a portable canister or cover. The collector may include a single stage or multiple stage concentration to focus light from foldable yet rigid reflective surfaces onto photovoltaic cells. In a single stage system, light is concentrated by a parabolic mirror directing sunlight onto arrays of photovoltaic cells. With a two stage solar concentration, the first concentration is made with a parabolic foldable umbrella. A 3-stage solar collector is also disclosed.

### CLAIM OF PRIORITY

### FIELD OF THE INVENTION

The present invention is generally related to solar cells, and more specifically to multi-functional and versitle solar arrays.

### BACKGROUND OF THE INVENTION

Solar cells, solar cell arrays and solar collectors continue to advance in both efficiency and configuration. There is desired an improved solar energy collector that is portable, multi-functional and efficient for a variety of uses and configurations.

Objects of the invention are a light weight foldable reflective umbrella for concentration of solar power onto a receiver of multiple photovoltaic cells. Water used to cool the photovoltaic cells is collected in the containing or supporting structure for the umbrella, therefore doubling solar energy collection via solar water heating in addition to photo-voltaic generation. Based on the foldable geometry of the parabolic mirror, we designed solar receivers with one to three stages of solar concentration.

Novel ways of folding blades of a parabolic surface allows the solar umbrella to be portable and protected from inclement weather. Relying on folding to avoid wind force also reduces the need for using large metal support structures. Our invention focuses on portable solar energy collection, allowing electrical and hot water generation on vehicles, and anywhere on the ground that sun is prevalent. The umbrella also provides shading and can be made part of a shelter; unlike most domestic solar panels which require roof top installation which can be expensive and inconvenient.

### SUMMARY OF THE INVENTION

The invention achieves technical advantages in a lightweight, small volume and highly portable solar electricity collector at low cost. In one preferred embodiment the device is configured as a solar umbrella. The solar umbrella is made up of components that are able to fold up into a small package and fit inside of a portable canister or cover. It uses single or multiple stage concentration to focus light from a foldable yet rigid reflective surface onto photovoltaic cells. In a single stage system, light is concentrated by a parabolic mirror directly onto arrays of photovoltaic cells. With a two stage solar concentration, the first concentration is made with a parabolic foldable umbrella. The second concentration is made with a conic receiver near the focal point of the parabolic umbrella onto the array of photovoltaic cells. Light can be concentrated greater than a 1000 times on a number of high efficiency photovoltaic cells. Another embodiment with three stage concentration includes a mirror close to the focal point to redirect light to the receiver located at the base of the umbrella where a conic type receiver concentrates the light onto the photovoltaic cells.

A container, or vertical support, for the umbrella also serves as a platform for sun tracking. The container or support can also serve the purpose of holding water for both cooling the solar receiver and generating hot water. The solar umbrella can be mounted in locations wherever a small flat surface with open access to the sun is available. The solar umbrella can be mounted on top of an electric vehicle (EV) with the umbrella deployed while the EV is parked, providing shade and electricity for the By. Electricity generated can be used in direct current (DC) faun for charging batteries or running DC appliances, or inverted into alternating current before connection to an AC receptacle. The solar umbrella can also be deployed in front of south facing windows as awnings while directly providing power for window air conditioners, TV, and computers without the need for connection to the electricity power grid. This significantly reduces installation and permit processing cost as well as time needed for photovoltaic generation. Additionally, the solar umbrella can be connected to the house electrical panel after the grid tie in, using a switch to alternate between the solar electrical supply and the grid supply. This alleviates co-phasing with the grid system as the solar receiver generated power is never in-line with the grid system. If so desired, the solar umbrella can be hooked into the grid system in a traditional style with co-phasing required at the electrical panel of the residence or building.

Novel techniques for sun tracking based on location, time, and photovoltaic feedback are utilized for accurate tracking of the sun.

### BRIEF DESCRIPTION OF THE DRAWINGS

FIG. 1 describes the analytical geometry of a parabola;

FIG. 2A shows the unfolded umbrella;

FIG. 2B shows the folded umbrella;

FIG. 3A shows how rigid sections of a parabola can be folded via two axis, first by rotation of the blades and then by inward folding;

FIG. 3B shows how rigid sections of a parabola can be folded via two axis, first by rotation of the blades and then by inward folding;

FIG. 3C shows how rigid sections of a parabola can be folded via two axis, first by rotation of the blades and then by inward folding;

FIG. 3D shows how rigid sections of a parabola can be folded via two axis, first by rotation of the blades and then by inward folding;

FIG. 4A shows the umbrella with 18 blades arranged in 4 layers;

FIG. 4B shows the umbrella with 18 blades arranged in 4 layers;

FIG. 4C shows the umbrella with 18 blades arranged in 4 layers;

FIG. 4D shows the umbrella with 18 blades arranged in 4 layers;

FIG. 4E shows the umbrella with 18 blades arranged in 4 layers;

FIG. 4F shows the umbrella resting on a center platform;

FIG. 4G shows the umbrella resting on a center platform;

FIG. 5A details each blade in the solar umbrella with 18 blades;

FIG. 5B shows detail of each blade in the solar umbrella with 18 blades;

FIG. 5C shows detail of each blade in the solar umbrella with 18 blades;

FIG. 5D shows detail of each blade in the solar umbrella with 18 blades;

FIG. 6A shows alternative methods of folding blades for the solar umbrella;

FIG. 6B shows alternative methods of folding blades for the solar umbrella;

FIG. 6C shows alternative methods of folding blades for the solar umbrella;

FIG. 6D shows folding the blades downward away from the focal point;

FIG. 6E shows folding the blades downward away from the focal point;

FIG. 7A shows one embodiment of the unfolded umbrella;

FIG. 7B shows one embodiment of the unfolded umbrella;

FIG. 8A shows how the integrity of the parabola comprising blades radiating from the center is maintained by lateral binding of the blades in the open position;

FIG. 8B shows how the integrity of the parabola comprising blades radiating from the center is maintained by lateral binding of the blades in the open position;

FIG. 8C shows how the integrity of the parabola comprising blades radiating from the center is maintained by lateral binding of the blades in the open position;

FIG. 8D shows how the integrity of the parabola comprising blades radiating from the center is maintained by lateral binding of the blades in the open position;

FIG. 8E shows how the integrity of the parabola comprising blades radiating from the center is maintained by lateral binding of the blades in the open position;

FIG. 9A details the optics of a concentric parabola;

FIG. 9B shows a Newtonian telescope;

FIG. 9C shows a two-stage concentrator;

FIG. 9D shows Solar Cell second stage cone-reflector;

FIG. 9E shows Solar Cell second stage cone-reflector;

FIG. 10A shows the Solar receiver with 6 cells;

FIG. 10B shows the Solar receiver with 6 cells;

FIG. 10C shows the Solar receiver with 6 cells;

FIG. 10D shows the Solar receiver with 6 cells;

FIG. 11A shows rectangular grid partitioning;

FIG. 11B shows rectangular grid partitioning;

FIG. 11C shows rectangular grid partitioning;

FIG. 11D shows rectangular grid partitioning;

FIG. 11E shows rectangular grid partitioning;

FIG. 11F shows front concentrating cone and receiving cell for a cell;

FIG. 11G shows front concentrating cone and receiving cell for a cell;

FIG. 11H shows front concentrating cone and receiving cell for a cell;

FIG. 11J shows front concentrating cone and receiving cell for a cell;

FIG. 11K shows various concentrator geometries;

FIG. 11L shows various concentrator geometries;

FIG. 11M shows various concentrator geometries;

FIG. 11N shows various concentrator geometries;

FIG. 11P shows concentric ring receiver layout;

FIG. 11Q shows concentric ring receiver layout;

FIG. 12A shows geometry of three stages of solar concentration;

FIG. 12B shows geometry of three stages of solar concentration;

FIG. 13A shows integration of solar water heating and solar photo-voltaic electricity generation;

FIG. 13B shows integration of solar water heating and solar photo-voltaic electricity generation;

FIG. 13C shows integration of solar water heating and solar photo-voltaic electricity generation;

FIG. 13D shows integration of solar water heating and solar photo-voltaic electricity generation;

FIG. 14 shows two axis mechanism for sun tracking for solar umbrella;

FIG. 15A shows use of solar umbrella on vehicles;

FIG. 15B shows use of solar umbrella on vehicles;

FIG. 15C shows use of solar umbrella on vehicles;

FIG. 15D shows use of solar umbrella on vehicles;

FIG. 16 shows use of solar umbrella as shading structures; and

FIG. 17 shows use of solar umbrella as part of a shelter.

### DETAILED DESCRIPTION OF THE PRESENT INVENTION

Structure of the Parabolic First Stage Concentrator

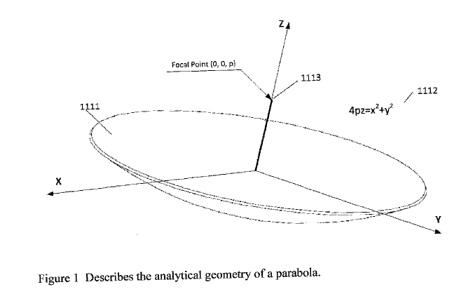

FIG. 1 shows a parabolic surface [1111] satisfying the equation x²−y²=4pz [1112]. The Cartesian coordinates (x, y, z) reflect light coming from a point source at the top (with incident light parallel to the z-axis) onto a single focal point at (x, y, z)=(0, 0, p) [1113]. Since the sun is not exactly a point source (at a distance of 93 million miles away, the sun of diameter 0.865 million miles extends an angle slightly less than 0.01 radians), the image of the sun at the focal point is not exactly a single point. This angular spread limits concentration of solar power to less than 40,000 times. In our practice, we prefer to concentrate solar power to at most 1000 times through a single or multiple stage concentration process.

We can use high efficiency solar cells to receive the focused light close to the focal point [1113]. One kind of high efficiency solar cells is the triple junction photovoltaic cells which are capable of more than 40% efficiency for converting greater than 1000 times focused sun energy into electricity. Though these cells are much more expensive per unit area than silicon based solar panels, the high solar concentration and doubled efficiency reduces the area needed per watt of power generation by about 2000 times. This high concentration of sunlight on expensive but highly efficient solar cells makes the case of concentrated photovoltaics (CPV) economically compelling in comparison with fixed solar panels. With solar tracking, CPV has up to an additional 50% generation increase over fixed panels over a 24 hour period. Our invention makes CPV very lightweight and highly mobile, significantly reducing the cost for the concentrating and tracking systems.

Two Axis Folding of Blades of Umbrella

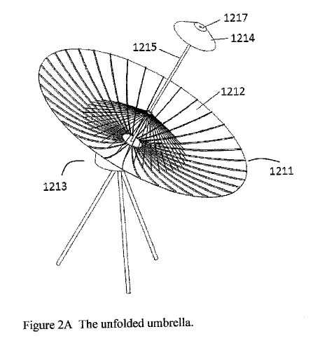

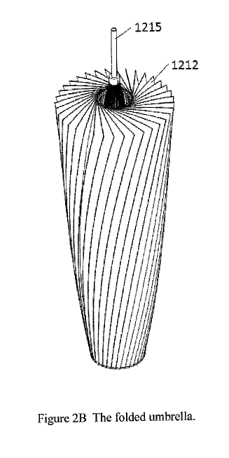

In FIG. 2A and FIG. 2B, we demonstrate the notion of using a foldable parabolic surface for solar generation. The system is intended to be placed directly on the ground or vehicle without expensive rooftop or supporting infrastructure installation. The parabolic surface while foldable, is rigid for each blade, unlike the usual umbrella made out of fabric. Fabric supported by umbrella ribs cannot maintain an accurate parabolic surface for a high degree of solar concentration. Thus the folding mechanism is quite different from typical umbrellas. The solar umbrella avoids the use of heavy glass and steel necessary for withstanding winds up to 100 mph by the simple act of folding. The compactly folded umbrella is intended for easy transportation.

One embodiment of the solar umbrella employs two axis rotation of the blades. In the folded position, the blades are packed with the length of the blades aligned with the center support and the width of the blades aligned in a radial direction. This requires the turning of the blades along two axis.

In FIG. 2A, we show an open umbrella [1211] comprising 36 blades [1212] as the first stage solar concentrator rested on a tripod support [1213]. The second stage solar concentrator [1214] rests on top of a support [1215] that also serves as conduit for electric wires and coolant. The concentrator [1214] focuses light through cones onto multiple solar cells [1217]. In FIG. 2B, we show a folded umbrella, which folds first by tilting each blade [1212] vertically before pulling in each blade towards the center support [1215].

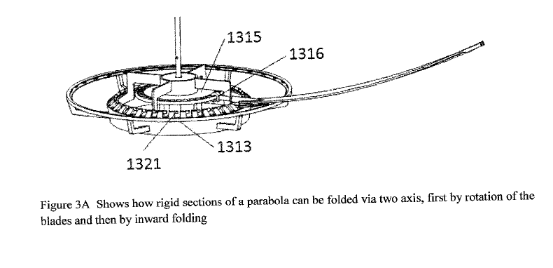

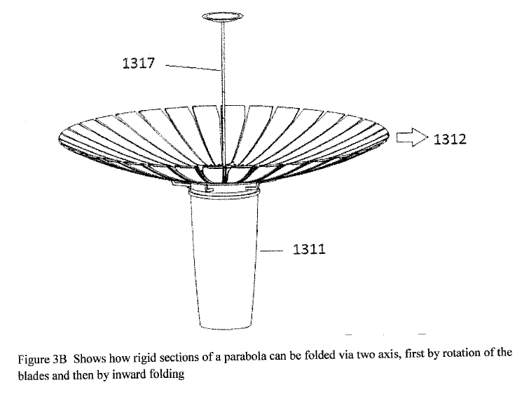

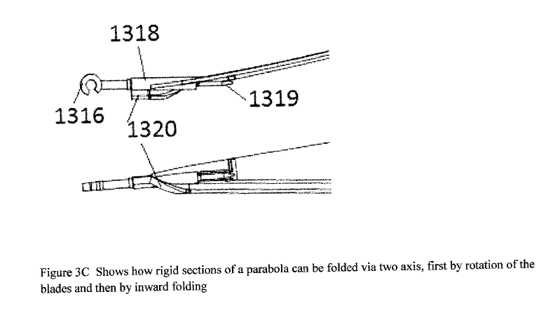

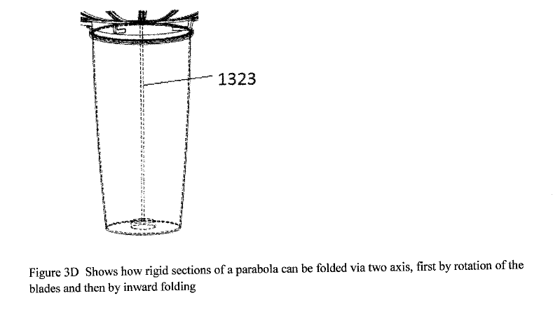

This two axis rotation of the blade is illustrated further in FIG. 3A-FIG. 3D. FIG. 3A-FIG. 3D shows a container [1311] for containing the umbrella [1312] with the top rim [1313] used to guide the folding of the blades [1314]. Each blade is hinged onto a center platform [1315] using a cuff [1316] that allows the movement of the blade towards the center [1317]. A separate hinge [1318] allows rotation of the blade along the length of the blade [1319]. A rail [1320] along the side of the blade is guided by a notch [1321] on the top rim [1313] of the container to facilitate the initial rotation of the blade [1314], as the lower part of the rail turns. The center platform [1315], guided by the center support [1323], moves downward and consequently pulls the blades first sideway and then inward in the process of folding the umbrella [1312] inside the container [1311].

Single Axis Folding of Blades of Umbrella

Another embodiment of the foldable solar umbrella requires only the folding of the blades inward towards the center support without the need to rotate the blade along its length as required in the previous two axis embodiment. The blades rest on different angles of inclination towards the center, allowing multiple layers of blades similar to the folding of petals of a rose.

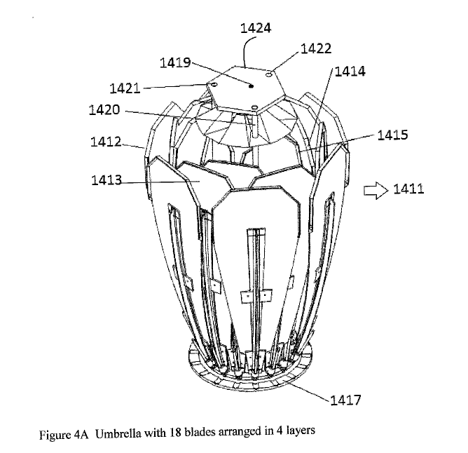

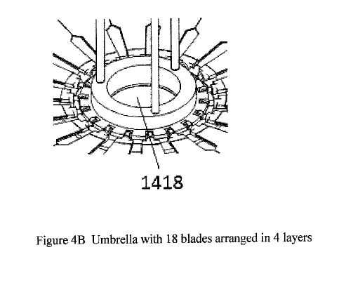

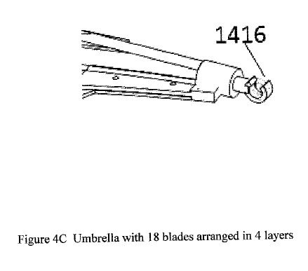

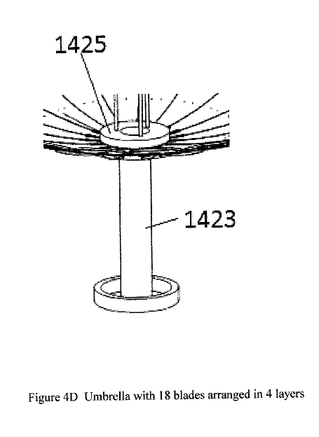

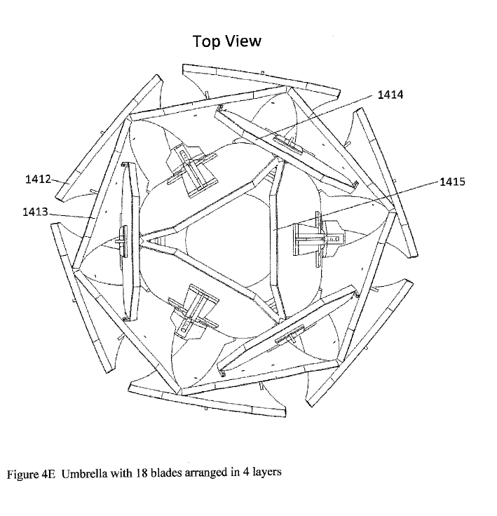

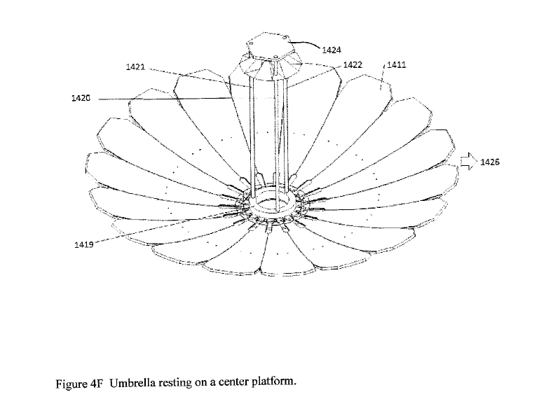

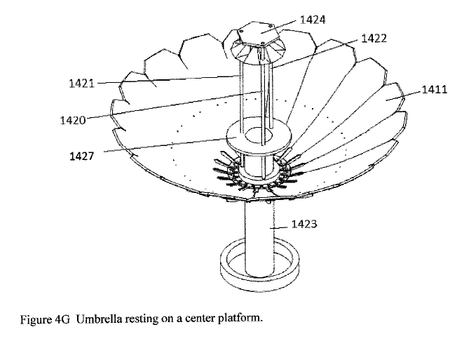

FIGS. 4A and 4B show an embodiment with 18 folded blades arranged into 4 layers [1412, 1413, 1414, and 1415]. Each blade has the same cuff holding onto the center platform [1417] to allow the blade to move towards the center [1418]. The solar receiver [1424] is placed close to the focal point [1419] of the opened parabolic mirror, being supported by three tubes [1420, 1421, and 1422] from the center platform [1417]. In this folded position, the blades enclose the center column [1423] and the solar receiver [1424]. Also the three tubes [1420, 1421, and 1422] surround the center column, with the solar receiver [1424] close to the top [1425], and the center platform [1417] close to the bottom of the umbrella structure.

This four layer folding geometry allows for fewer blades (18) than that of a two axis folding (36), while the umbrella folds almost as compact, as shown in FIG. 4A and FIG. 4E. The choice of 18 blades is given by the arithmetic of 18=6+6+6, with three concentric layers each of 6 folded blades. It is also observed that the innermost layer of 6 blades could be more compactly folded into two layers of three blades. This arithmetic exhibits the best symmetry discovered so far for the purpose of compact folding.

The image of FIG. 4F shows the open umbrella [1426] with the 18 blades [1411] resting on the center platform, which has now moved to the top of the center column [1423] with a top stopper [1427]. It can be compared to the closed position at the bottom in FIG. 4a. The solar receiver [1424] now moves further up above the center column [1423] keeping the receiver placed at the focal point of the now open parabolic umbrella [1426]. The image of FIG. 4G shows the blade platform one third of the way from the top of the center column [1423] in a partially unfolded position.

Besides supporting the solar receiver [1424], the three tubes in FIG. 4F and FIG. 4G [1420, 1421, and 1422] also serve the purpose of transporting coolant up to and down from the solar receiver, as well as wires for electricity transmission.

The center column [1423] provides support for the umbrella, and can also be used for containing water, either heated by the solar receiver or cooled by electricity generated by the solar umbrella. Also, the column and the blades can be utilized as architectural elements of a shelter. The umbrella itself provides shading and roofing, instead of requiring roofing for the placement of solar panels. The center column can also be used to support other tent or canopy structures besides the solar umbrella.

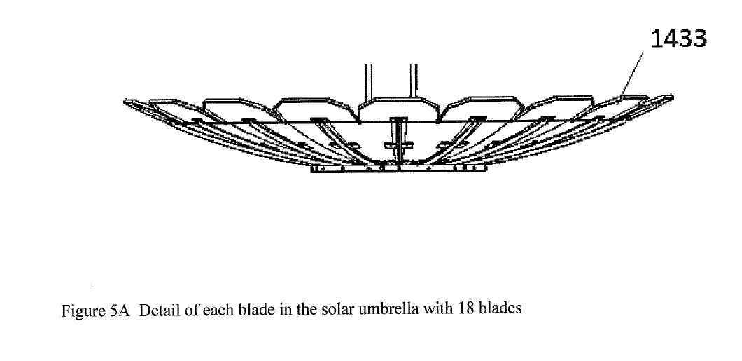

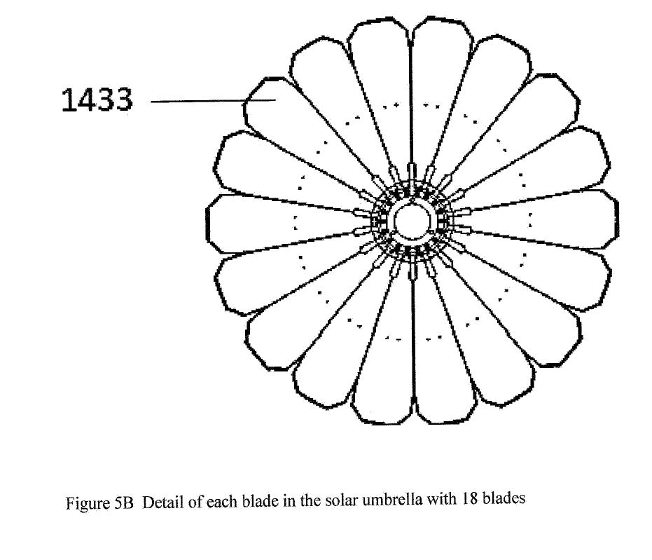

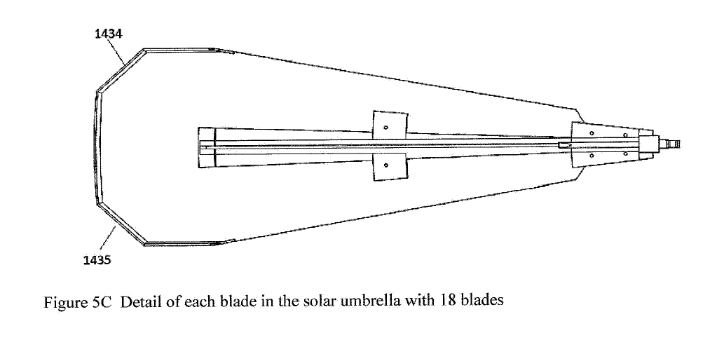

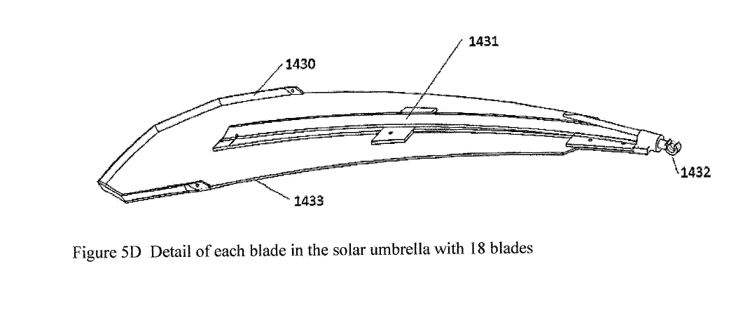

The detail of each blade is shown in FIG. 5A-FIG. 5D. One material possible for fabrication of the blade is polycarbonate, a type of plastic which is strong and can be heated and vacuum formed into the desired curvature. Crease lines [1430] are added to strengthen the structure. Also, a spine [1431] provides strength along the length of the blades. The bottom of the spine contains a cuff [1432] that hinges on the center platform allowing the inward folding of each blade. The blade is reflective on the convex upper side [1433], either by means of vapor deposition of reflective metals such as aluminum, or by placement of a reflective film.

The corners of the blade [1434 and 1435] are cut in order to reduce the radius of the 4 layers when folded. This corner cutting also gives a unique signature of flower petals enhancing the aesthetics of the umbrella when fully deployed.

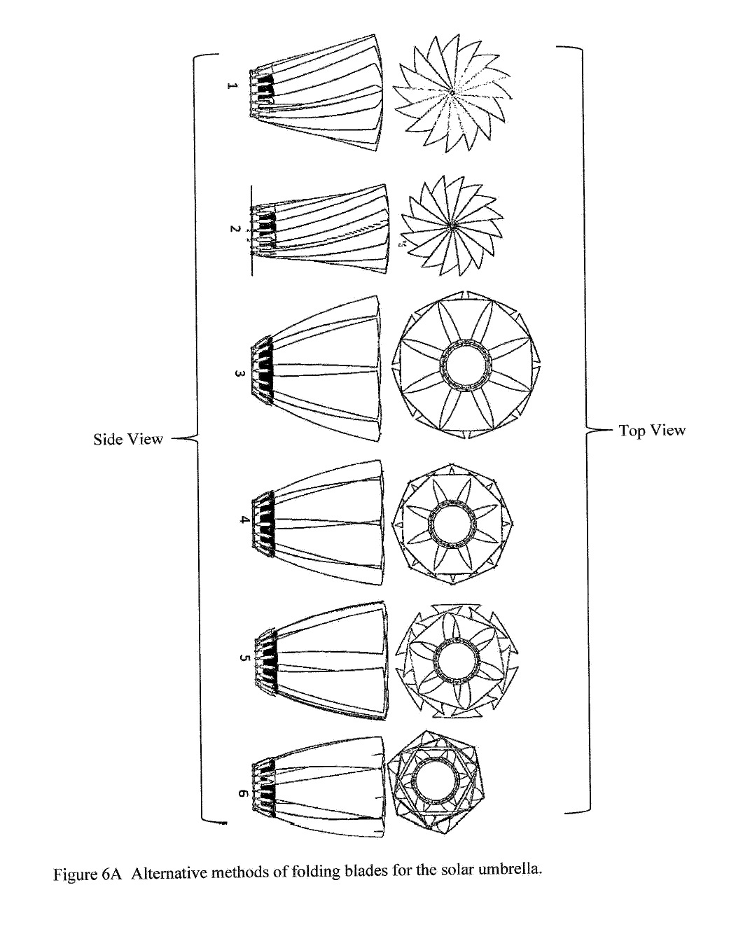

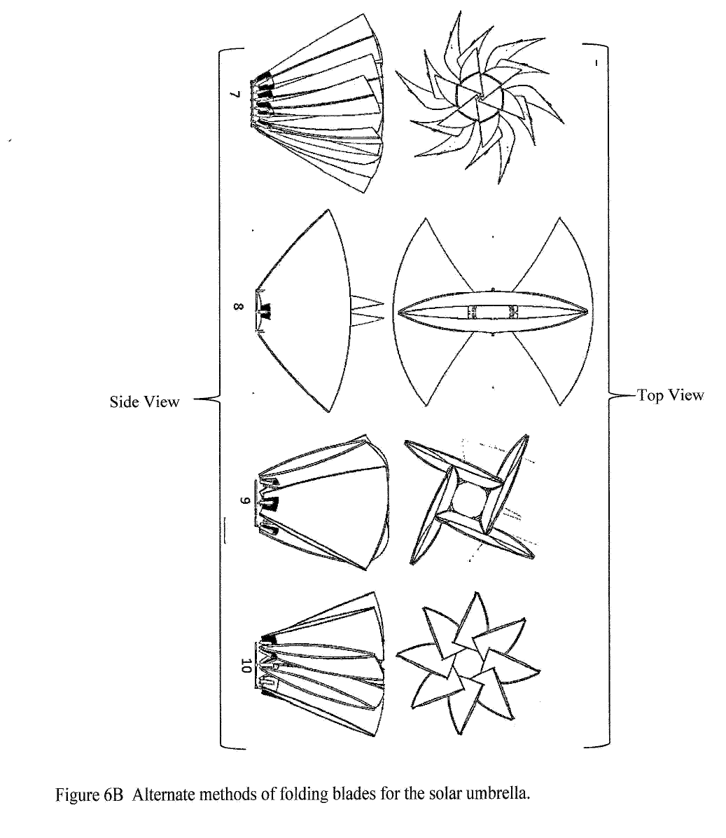

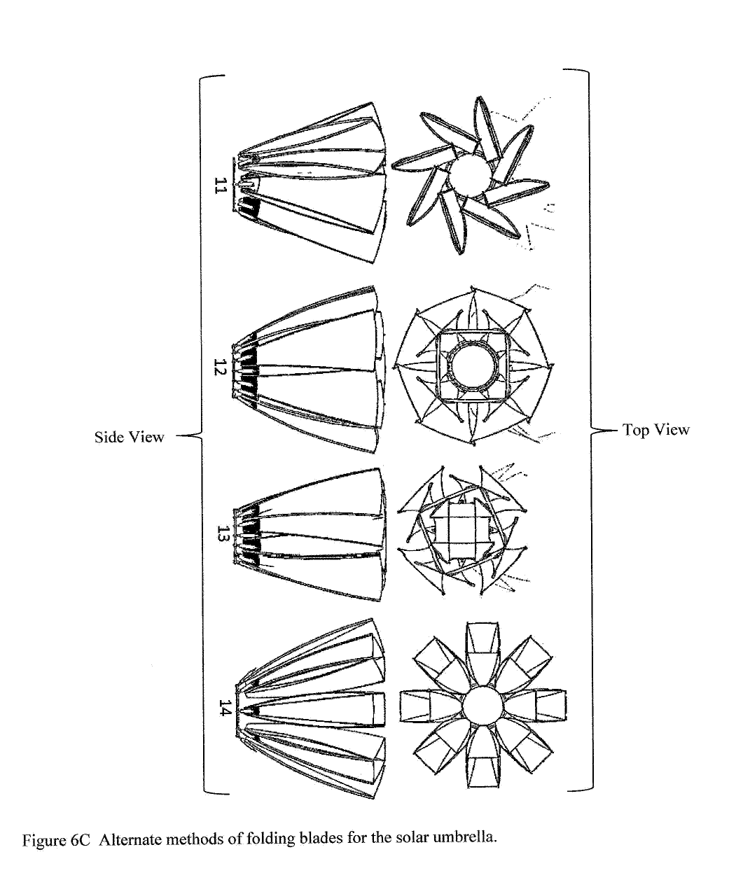

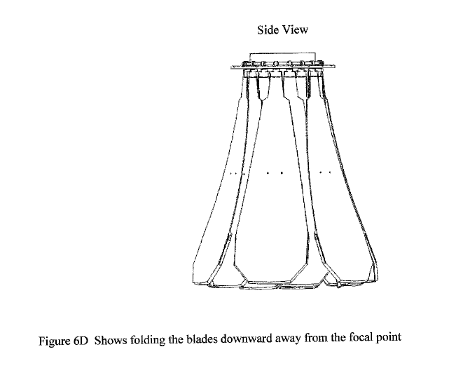

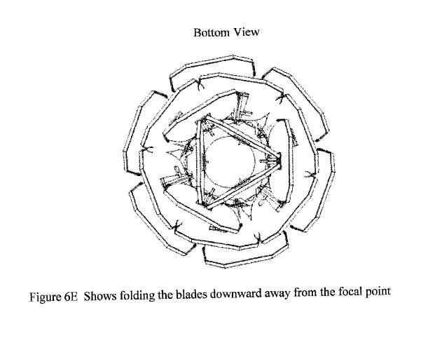

While the four layer folding of 18 blades is the most promising, other possible embodiments of folding blades are shown in FIGS. 6A, 6B, 6C. The top view is shown above the side view for each design. Each design folding pattern is described in Table 1 below.

TABLE 1
Several alternate design options for folding blades in umbrella.

| De- | Total # | |
|---|---|---|
| sign # | Blades | Blade Fold Pattern |
| 1 | 16 | 1 row of 16 blades with rotation of each blade |
| 2 | 16 | 1 row of 16 blades with rotation and each blade edge |
| | | clipped |
| 3 | 16 | 2 rows of 8 blades with no rotation of blades |
| 4 | 16 | 2 rows of 8 blades with no rotation and each blade |
| | | edge clipped |
| 5 | 18 | 3 rows of 6 blades with no rotation |
| 6 | 18 | 3 rows of 6 blades with no rotation and each blade |
| | | edge clipped |
| 7 | 18 | 3 rows of 6 blades with rotation and fold and each |
| | | blade edge clipped |
| 8 | 4 | 2 rows of 2 blades each folded up with no rotation |
| 9 | 8 | 2 rows of 4 blades, with 2 blades first folded in half |
| | | on top of one another, then all folded upwards |
| | | towards center |
| 10 | 16 | 1 row of 16 blades, with 2 blades first folded in half |
| | | on top of one another, then all folded with rotation |
| | | upwards towards center |
| 11 | 16 | 1 row of 16 blades, with 2 blades first folded in half |
| | | on top of one another, then all folded upwards |
| | | towards center |
| 12 | 16 | 4 rows of 4 blades with no rotation |
| 13 | 16 | 4 rows of 4 blades with no rotation and each blade |
| | | edge clipped |
| 14 | 8 or 16 | 1 row of 8 blades, with each blade folded into 4 |
| | | sections on top of itself, then all blades folded |
| | | upwards towards center |

Alternatively to folding the blades upwards towards the focal point, we may also fold the blades downward away from the focal point. An example of this can be seen in FIG. 6D and FIG. E which shows the side and bottom view of blades folded downward away from the focal point. FIG. 6D shows an embodiment with 18 folded blades [1611] arranged into 4 layers [1612, 1613, 1614, and 1615]. Each blade has the same cuff [1616] holding onto the center platform [1617] to allow the blade to move towards the center.

Mechanisms for Umbrella Unfolding and Maintaining Parabolic Integrity

Dividing the parabolic surface into blades simplifies manufacturability by allowing smaller parts to be built in order to form a large parabola. Additionally, it facilitates the need of folding for the purposes of compactness, transportation, and of protection against wind force. Using multiple blades in our system necessitates two mechanisms: first how the umbrella unfolds and reassembles into a single parabolic surface, and second how the blades may be structurally bound to form a rigid and integral parabolic structure sound enough to withstand weight and wind without breaking up or deforming

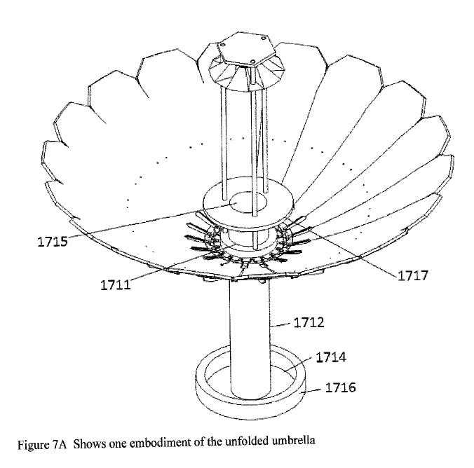

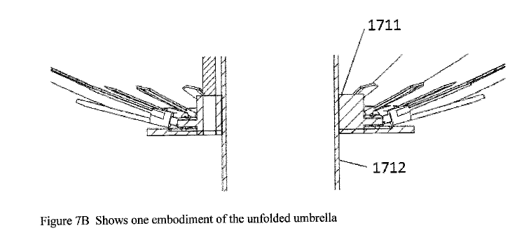

One embodiment of the umbrella unfolding is shown in FIG. 7A and FIG. 7B. The center platform has a hollow center [1711] with inner diameter equal to the outer diameter of the center column [1712], thus allowing the center platform to move up and down the center column. The movement can be powered manually or motorized. The motion is delimited at the bottom [1714] in the closed position and at the top [1715] in the open position by stoppers. The bottom stopper [1714] can also facilitate the layered closure of the blades by means of differing lengths of cusps [1716] that force the closure. The top stopper [1717], besides delimiting the upward movement of the parabolic surface, also presses down on the blades to prevent upward motion of the blade. The top stopper, together with the center platform, sandwiches the blades in a rigid opened position for solar concentration.

Nevertheless, the light weight plastic or polycarbonate surfaces could flex in various directions, thus deforming the parabolic surface. As a result, the mirror would not properly focus. The creasing of the edge of the blade, and the addition of a long spine along the length of the blade provides a degree of integrity of the parabolic shape of each blade.

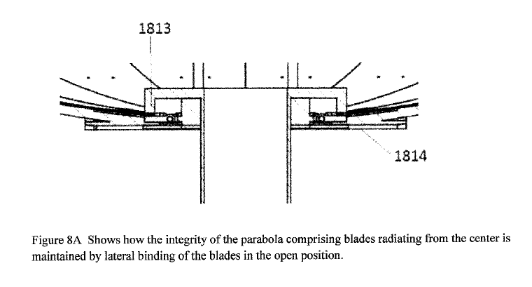

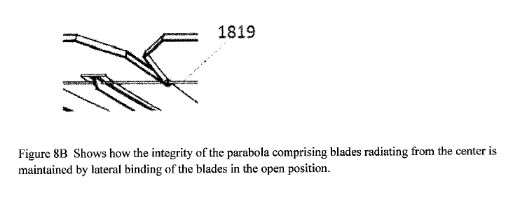

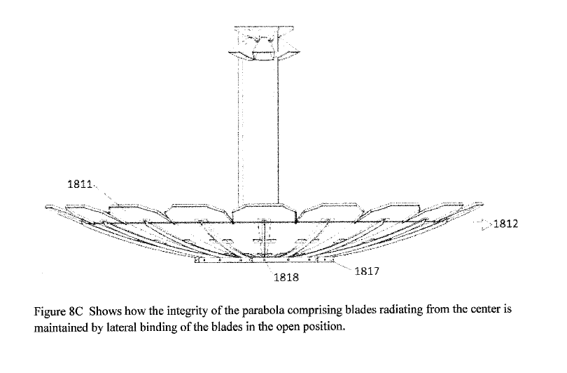

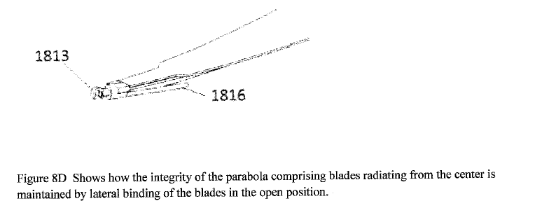

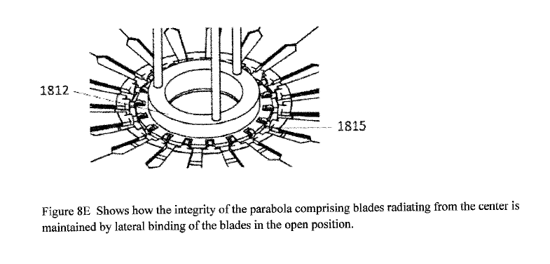

Since the round parabolic surface is divided into multiple blades, the integrity of the parabola comprising blades radiating from the center is maintained by lateral binding of the blades in the open position of the umbrella as shown in FIG. 8A-FIG. 8E. In our current embodiment of the 18 blade [1811] solar umbrella [1812], there are four possible lateral binding mechanisms. The first and innermost binding mechanism is provided by the cuff [1813] holding each blade [1811] onto a fixed position [1814] on a ring [1815]. The second binding mechanism is provided by the sandwich structure of the blades by the center platform [1812] and the top stopper [1813]. Further out is the third binding mechanism that conjoins a spire [1816] from each blade through a binder [1817] that the spires pierce through [1818]. Close to the circumference, we may lock adjacent blades together, for example by stringing [1819]. Aldo adjacent blades can be held together using several techniques including clips or magnets. Through these mechanisms in combination, the flexing of the blades can be greatly reduced or prevented.

Two Stage Solar Concentration and Structure of Solar Receiver

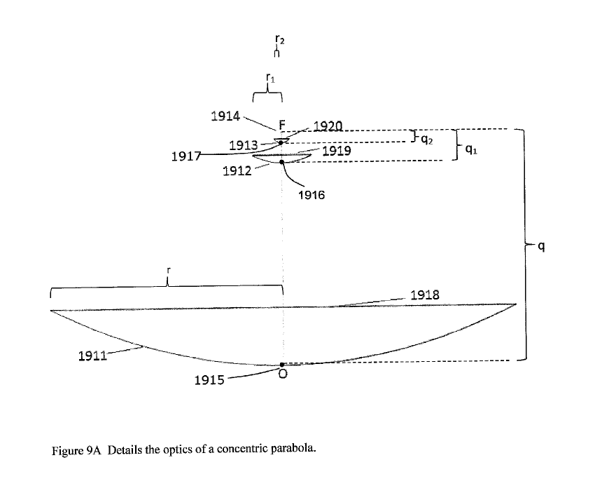

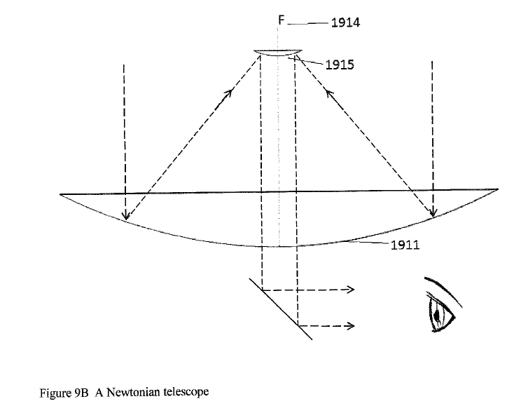

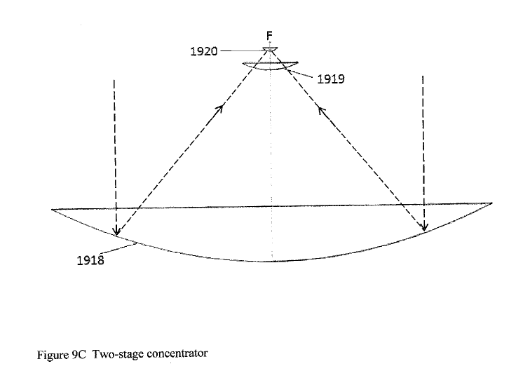

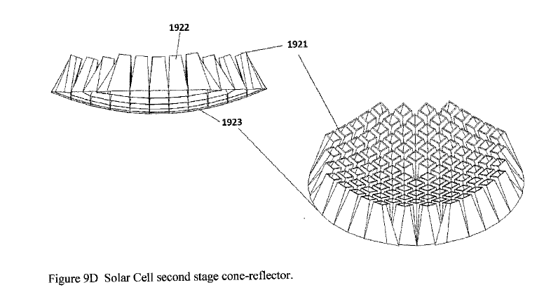

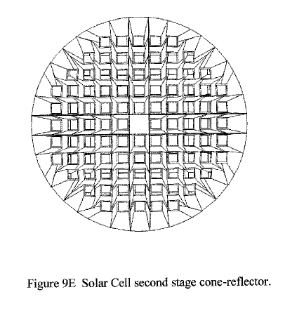

The two stages solar concentrator is shown in FIG. 2A with the first stage being the parabolic dish. The second stage is a conic receiver further concentrating sun light on solar cells. In one embodiment, we adopt a parabola of diameter of r=4 meters from rim to rim. The mirror has a flat receiving area of A=πr²=12.5664 square meters as shown in FIG. 9A [1918].

The conic receiver has a flat receiving area of A₁=πr₁² [1919]. If r₁=½ meter, then A₁=0.19635 square meters. We may perceive the solar cell as covering a flat circular area of A₂=πr₂². If r₂=⅛ meter, then A₂=0.012272 square meters [1920] or 122.72 square centimeters.

Assuming that all sunlight is reflected from the parabolic first stage concentrator of area A, plus all such reflected light is collected by the second stage concentrator of area A₁, and that all such collected light is concentrated further onto the solar cells of area A₂, we have the concentration ratio of the first stage concentrator as A/A₁ (=64 in one embodiment) and of the second stage concentrator as A₁/A₂ (=16 in one embodiment). The combined concentration ratio of the two stages of concentrators is given by the product of these two concentration ratios, i.e. A/A₂ (=1024 in one embodiment).

Actual light captured by the first stage concentrator is reduced by the shadowing of second stage concentrator onto the first stage concentrator. Each of the corresponding areas A, A₁, and A₂ could be proportionally reduced by a hole in their respective center. Hence the concentration ratios are not changed by this shadowing.

To explain the concept of multiple stage light concentration, consider a compound lens or curved mirrors for a Newtonian reflective telescope. Consider three parabolas [1911, 1912, and 1913] with the same focal point F [1914] as shown in FIG. 9A. The radii of the parabolas are given respectively as r, r₁, and r₂. We now consider the vertical placement of these three surfaces, given respectively as q, q₁, and q₂, measured from the focal point of the parabola to the center of parabolic surfaces O [1915], O₁ [1916] and O₂ [1917] assuming all three parabolic surfaces have the same focal point F as the first stage parabola as shown in FIG. 9A. The flat surface area of these parabolic surfaces are given by A [1918], A₁ [1919], and A₂ [1920]. In fact, these parabolic surfaces constitute the sunlight catching surfaces of the two stage concentrators mentioned earlier.

We call these three parabolas co-focal on the same focal point F. A Newtonian telescope shown in FIG. 9B has two co-focal parabolas with the bottom mirror [1911] being convergent for light reflected upward onto the focal point F [1914] and the top mirror [1915] being divergent reflecting light downward. The combined convergent-divergent co-focal parabolic mirror magnifies light intensity at a ratio of A/A₁.

In one embodiment of a solar concentrator as shown in FIG. 9C, we further concentrate light captured by the second surface [1919] onto the third surface [1920] where solar cells are placed. The solar cells would reside on the third surface [1920], and the incident light should be as perpendicular to the solar cells as possible. The third surface can be a spherical surface centered at F, instead of a co-focal parabolic surface focused at F. Each solar cell [1921] has its own cone [1922] capturing light from part of the second surface [1923] onto the surface of the cell, as shown in FIG. 9D and FIG. 9E. The cones [1922] can be designed in multiple geometries to best collect and direct the light to the surface of the cells. The edge of the outside cones [1922] can additionally have a compound parabolic conic shape to help capture stray light. This would give the overall structure a ‘skirt’ look.

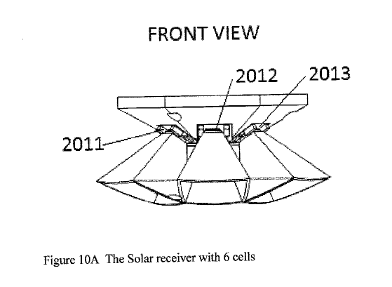

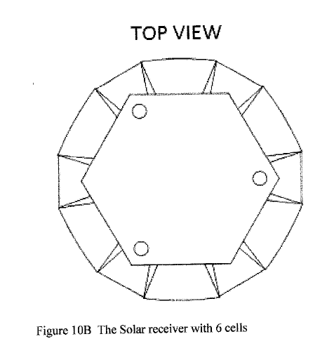

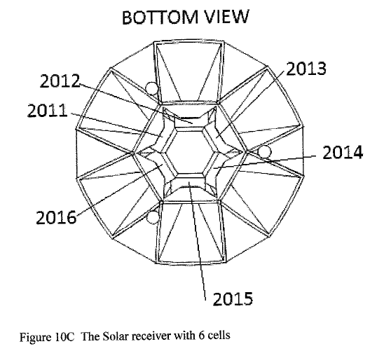

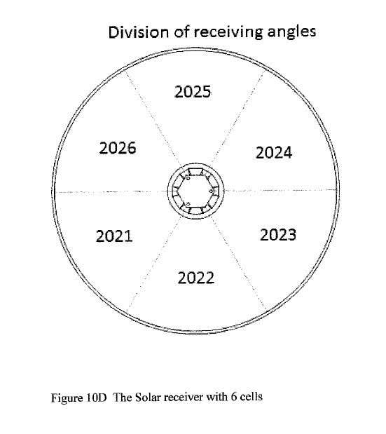

FIG. 10A-FIG. 10D shows a solar receiver with bottom, front, and top view. The solar receiver has 6 solar cells [2011-2016]. In an embodiment with a 1 meter diameter solar umbrella, we determined that a second stage concentrator/receiver with 6 solar cells is effective. The question is how the second and third surfaces should be partitioned for these 6 cells. We chose a circular arrangement with symmetry for the 6 cells. The partitions of the second surface for the cells [2011-2016] are respectively the first surfaces [2021-2026] on the 1 meter parabolic primary reflector.

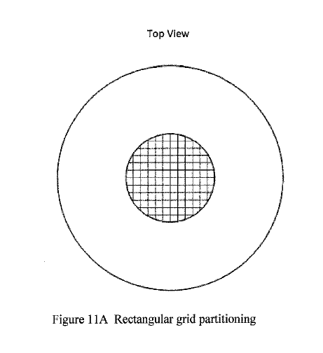

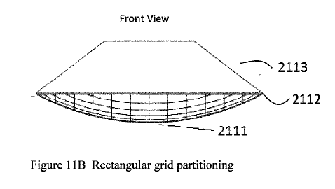

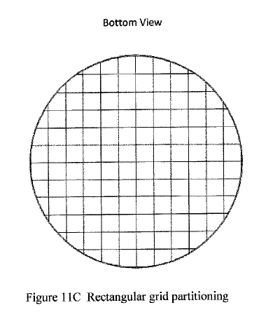

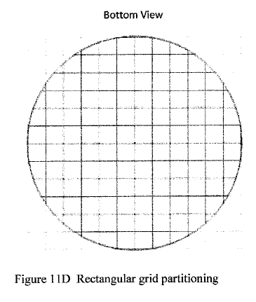

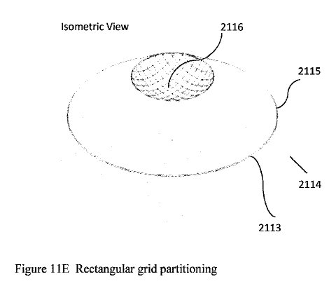

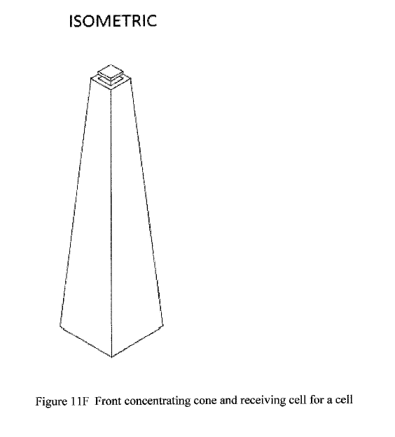

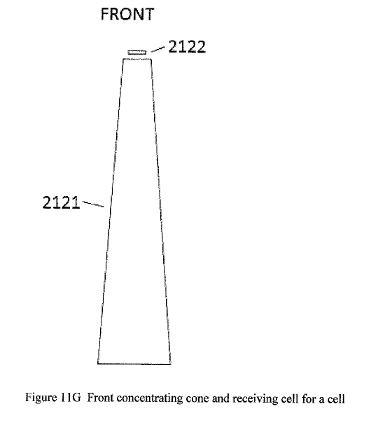

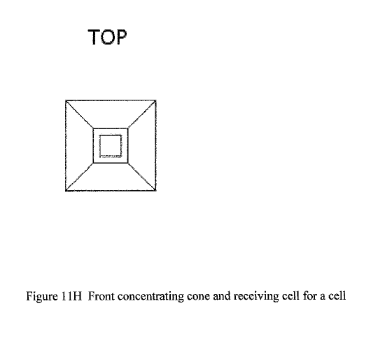

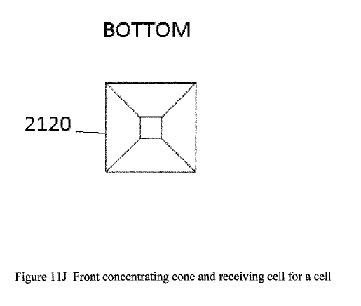

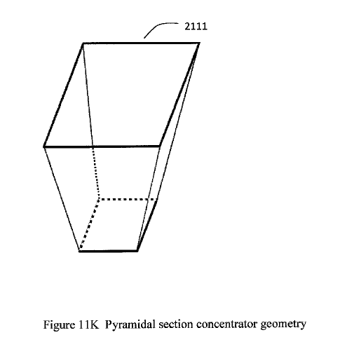

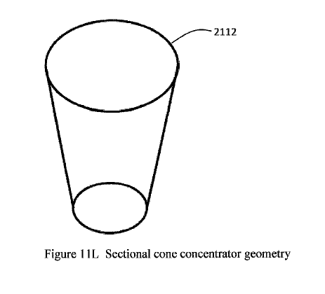

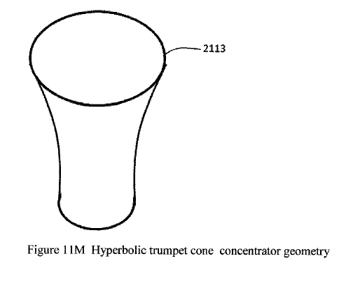

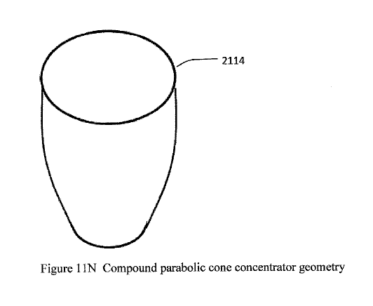

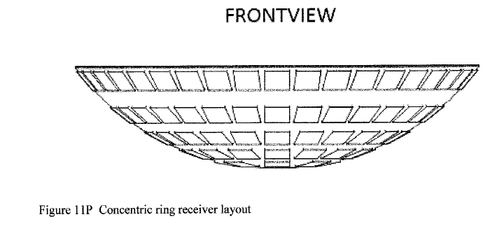

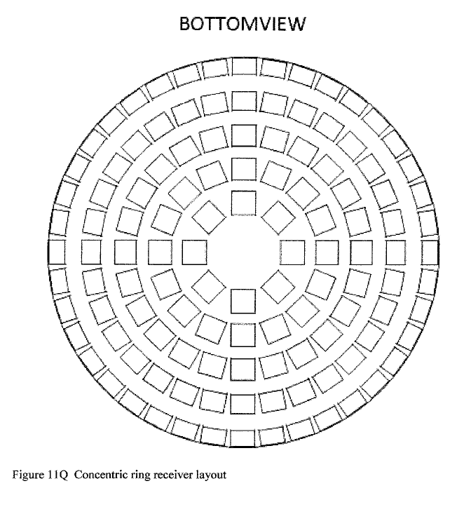

The principle of how the second surface is partitioned is better explained in FIG. 11A-FIG. 11E. A solar receiver with 120 cells is shown from the bottom, top, and front views. The design objective is to capture all the light reflected from the first surface, and to equally distribute the light to each cell. This is achieved by observing the following principle: equal area of the first surface [2011-2016] surface as seen from a bottom view (towards the entrance of the solar receiver) receives an equal amount of reflected light from the first surface.

This principle can be proved by examining the Newtonian telescope of FIG. 9B. An area of the second surface seen bottom up on the top mirror reflects straight down on the same flat area. Therefore equal areas seen bottom up receives the same power.

This principle is used in designing a rectangular grid partitioning as shown in FIG. 11A-FIG. 11E, displaying top, front, bottom and isometric views. We can divide the circular surface [2111] of the front entrance [2112] of the second stage concentrator [2113] according to a grid of squares [2114] of equal area. This works well except at the boundary of the circular surface [2115], or at the center [2116]. Nevertheless, we strive to equal the areas of [2114], [2115], and [2116]. We attempt to eliminate some squares of the grid as shown in FIG. 11A-FIG. 11E, including 4 squares in the center and 5 squares in each of the four corners of the grid with 12×12=144 squares. Thus we have a partition of 144−4−5×4=120 sections each with a solar cell. The front [2120], concentrating cone [2121], and receiving cell [2122] are shown for a cell in FIG. 11F-FIG. 11J. The front surface of the second stage receiver is parabolic, but the rear receiving surface is spherical. An alternative partition of the second parabolic surface can be done in concentric rings instead of a rectangular grid, as shown in FIG. 11P-FIG. 11Q.

Because spacing is required between the triple junction photovoltaic cells for electrical connections and by-pass diodes, the secondary concentrator collects and directs the light to the cell surface while allowing spacing for additional functions. The second stage receiver can have geometries in multiple shapes as shown in FIG. 11K-FIG. 11N These designs can include a pyramidal section [2111], sectional cone [2112], hyperbolic trumpet cone [2113], and a compound parabolic cone [2114]. Various geometries have properties which are optimal for different embodiments. Our design best utilizes a compound parabolic concentrator for capturing and redirecting light as the final concentrator to the chip surface.

For better generating efficiency, all light collected on a solar cell should be within a small range of incident angle to the solar cell. Light should fall as perpendicular to the surface of the cell as possible. This two stage concentration works better with more cells in a receiver; as the cell number increases, each cell receives light in a reducing range of incident angles. The design of FIG. 10A-FIG. 10D (1 meter diameter dish with a 0.5 meter focus length) with 6 receiving cells has light deviating more than 20 degrees from the normal of the cell surface. The design of FIG. 11A-FIG. 11E (4 meter diameter dish with a 2 meter focus length) with 120 receiving cells has light deviating less than 3 degrees from the normal of the cell surface.

A single cell for a smaller mirror would have an unacceptable large range of incident angles for sun rays. Prior art often uses a simple small mirror or lens for a single cell. A three stage design is often used for a single cell implementation. Our multiple cell design allows a simpler two stage design without loss of efficiency. We next describe a multiple cell design for three stage solar concentration.

Three Stage Solar Concentration and Structure of Solar Receiver

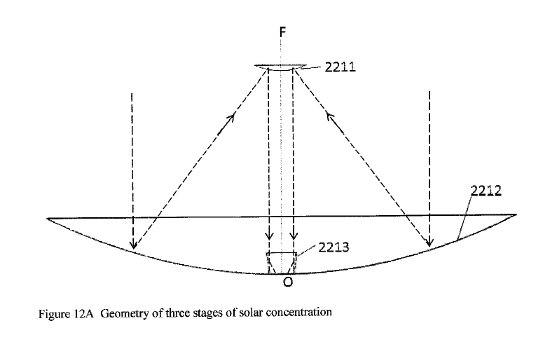

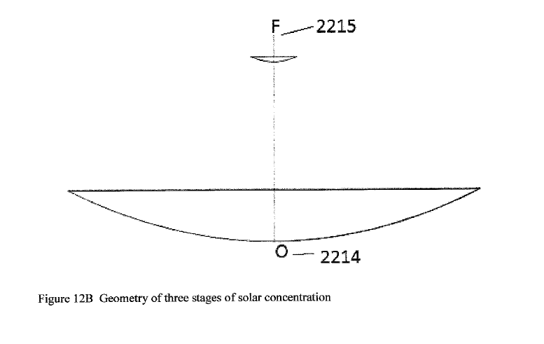

A three stage solar concentration is a simple adaptation of the Newtonian telescope, with a top mirror reflecting downward light to be concentrated near the center O of the parabola as shown in FIG. 12A and FIG. 12B. This design, as mentioned earlier, de-collimates the light at the second parabolic surface [2211] that was collimated at the first parabolic surface [2212]. The now almost parallel light converges onto a conic concentrator [2213] with one or more solar cells at the bottom of that cone.

The mathematics of combined focal length of compound lens or mirror telescope is well known. We re-derive here the mathematics under our special context of solar PV electricity generation.

We refer to the Cartesian coordinate system with O [2214] as the point (0, 0, 0). The focal point is F [2215] at (0, 0,f₁). The focal length of the top mirror is f₂. For the Newtonian telescope, the top mirror has its center O₂ placed at (0, 0, f₁-f₂) so that light reflected off the top mirror now travels parallel and straight down. If we move the top mirror up further by a distance of ε, the focal point of the compound mirrors now shift up from −∞ towards O [2214]. Suppose the new focal point with this shift is at (0, 0,f). We have derived the equation

$$f = 2 d - \frac{{f}_{1} {f}_{2}}{ɛ}$$

where d is the vertical separation of the centers of the two parabolas, or in other words d=f₁−f₂−∞. The equation for f can be validated for special cases. If ε=0 as in the case of Newtonian telescope, we have f=−∞. If d=f₁, then

$$ɛ = {f}_{2} and f = 2 d - \frac{{f}_{1} {f}_{2}}{ɛ} = 2 {f}_{1} - \frac{{f}_{1} {f}_{2}}{{f}_{2}} = {f}_{1} ,$$

which indicates the combined focal length is at the center of the second parabola, now placed at the focal point of the first parabola. This again checks, which indicates as we shift the second mirror up, the focal point f has moved from −∞ upward.

Thus we can solve for a desirable f the shift ε needed by solving the pair of simultaneous equations

$$f = 2 d - \frac{{f}_{1} {f}_{2}}{ɛ} and d = {f}_{1} - {f}_{2} - ɛ .$$

Of special interest is the special case of f=0. Straight forward algebra would indicate that the shift ε is roughly half way, i.e. ε˜½f₂.

In practice such as for ε=0 and a cone placed at O concentrates light by means of reflection onto a single chip at (0, 0, 0). Similar arrangement can be made for multiple cells.

Further Applications

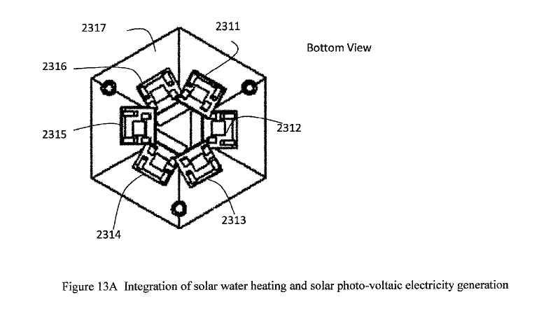

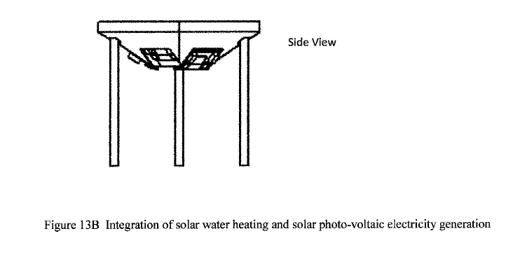

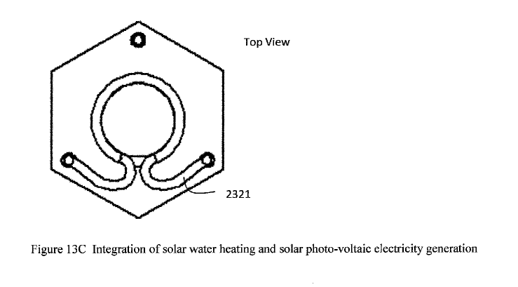

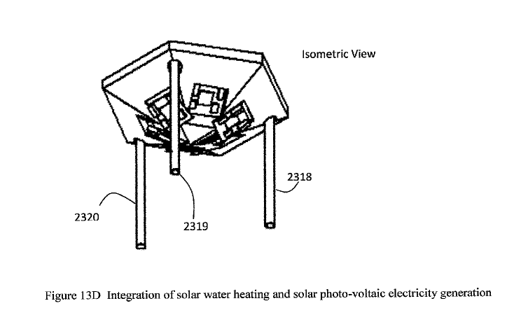

As shown in FIG. 13A-FIG. 13D, the triple junction photovoltaic solar cells [2311-2316] are position onto the solar receiver [2317] which is held into place by the three support tubes [2318-2320] near the focal point above the parabolic dish. The three support tubes can be used as conduit for electrical cables, cooling water from a tap source, as well as the coolant to cool the chips from a closed circulating system. As sunlight is focused onto the triple junction photovoltaic cells, they produce electricity and by-product heat. The by-product heat can be dispersed by passive cooling methods, air cooling by fans, or active liquid cooling. Using an active cooling method can recapture some of the heat energy for additional conversion into electricity, or for hot water generation. A cooling tube [2321] can be routed through the solar receiver [2317] to remove/capture the heat from the cells and surrounding area. Other alternate designs of liquid heat exchanger systems can be implemented in a similar fashion. The heated liquid is then moved to a separate location to either be used in a secondary electricity generation method, directly used as hot water, or exchanged to heat hot water for external use.

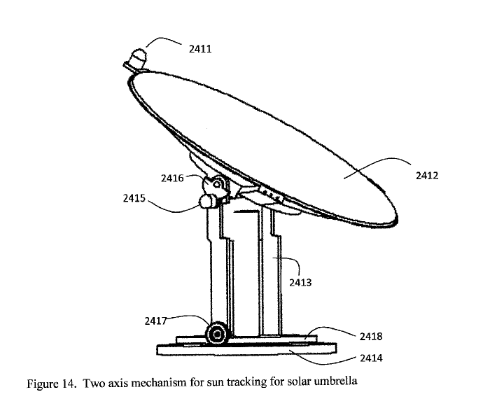

The solar umbrella requires tracking of the sun to provide optimum production from the triple junction solar cells. FIG. 14 shows a two axis mechanism for sun tracking for the solar umbrella. The sun tracking sensor [2411] detects the elevation and the azimuth of the sun. The parabolic umbrella [2412] is supported on the tracker by the support stand [2413] attached to the base [2414]. A motor [2415] rotates the dish on the elevation tracking hinge [2416] as guided by the sun tracking sensor to direct the dish as the sun changes elevation. A second motor [2417] near the base [2414] drives the azimuth tracking [2418] of the sun by rotating the dish supported by the support stand [2413].

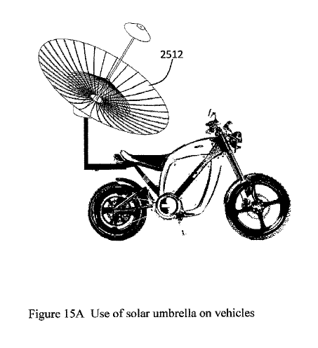

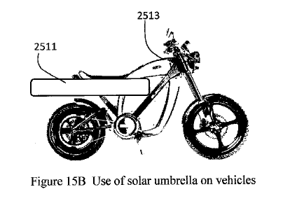

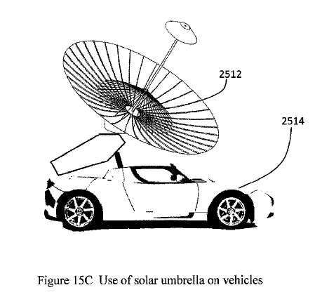

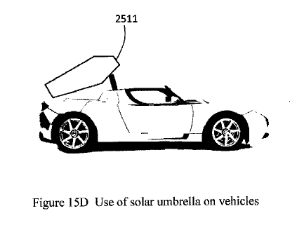

The solar umbrella can be used on electric vehicles as onboard chargers for use when the vehicles are parked. The solar umbrella is stored in a holding canister [2511] when folded. During use, the solar umbrella [2512] is deployed above the electric vehicle and charges the onboard batteries. Upon usage of the electric vehicle, the umbrella is again stored into the holding canister. FIG. 15A-FIG. 15D shows use of solar umbrella on either electric motorcycles [2513] or electric vehicles [2514]. The umbrella can also be used on an electric vehicle as a portable power supply. The power output from the solar umbrella can be routed to a DC or AC receptacle for external devices requiring power.

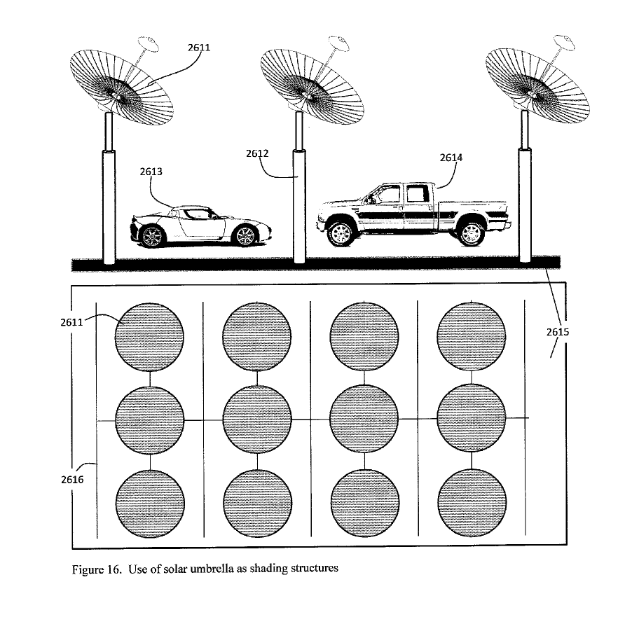

Solar umbrellas can be deployed in parking lots as shown in FIG. 16 for power generation, as well as shading structures. The solar umbrellas [2611] are placed on stands [2612] to give proper clearance for vehicles [2613-2614] to park underneath within a parking lot [2615]. The solar umbrellas [2611] can be positioned equally in a standard parking space [2616] so that partial shading of each parking space is achieved. Tighter packing density of solar umbrellas than what is shown in FIG. 16 can be achieved to obtain greater shading and higher power generation per area.

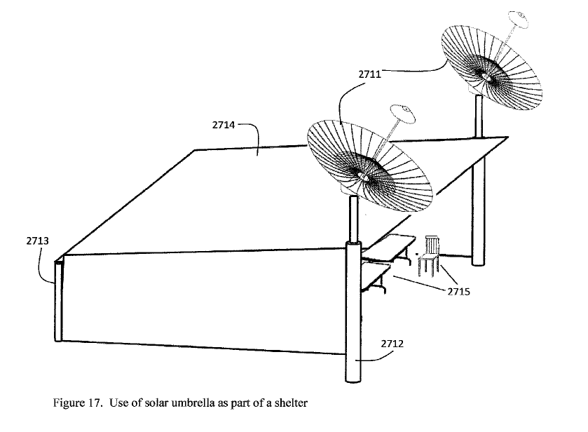

Temporary shelters can be assembled using the solar umbrella as, or part of, the support structures. FIG. 17 shows the solar umbrella as part of a shelter. The solar umbrellas [2711] are used as corner mounting supports in conjunction with other post [2713] upon which a cover or tarp [2714] can be tied or secured. The umbrellas could be mounted on support stands [2712] to create a taller structure if desired. Furniture [2715] or equipment can be placed within the structure where the solar umbrellas provide both electricity and protection from the environment, In addition, the solar umbrellas could provide a controlled temperature through heating or cooling, as well as hot water.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

1. A foldable solar collector, comprising:
a first reflector member configurable in a closed position, and configurable in an open position forming a generally parabolic shape and parabolic surface configured to collectively reflect and concentrate sunlight; and
a solar receiver configured to receive the concentrated sunlight from the first reflector member and convert the sunlight to usable energy.

2. The solar collector as specified in claim 1 wherein the first reflector member comprises a plurality of members.

3. The solar collector as specified in claim 2 wherein the plurality of members are configured to fold in the closed position.

4. The solar collector as specified in claim 3 wherein a first set of the plurality of members form a first layer when folded inwardly.

5. The solar collector as specified in claim 4 wherein a second set of the plurality of members form a second layer about the first layer when folded inwardly.

6. The solar collector as specified in claim 5 wherein the second set of the plurality of members overlap interfaces of the first set of the plurality of members and form a generally rose-like shape.

7. The solar collector as specified in claim 6 wherein the second set has more members than the first set.

8. The solar collector as specified in claim 3 further comprising a base member coupled to the plurality of members.

9. The solar collector as specified in claim 7 whereing the plurality members each have an end adjustably connected to the base member.

10. The solar collector as specified in claim 9 further comprising a support member adjustably coupled to the base member.

11. The solar collector as specified in claim 10 wherein the support member is telescopically coupled to the base member.

12. The solar collector as specified in claim 2 wherein the solar receiver is positioned above the parabolic surface.

13. The solar collector as specified in claim 2 wherein the solar receiver is positioned below the parabolic surface.

14. The solar collector as specified in claim 2 further comprising a second reflector member configured to receive the concentrated sunlight from the first reflector member and concentrate the received sunlight to the solar receiver to form a multi-stage concentrator.

15. The solar collector as specified in claim 14 wherein the second reflector member is positioned before a focal point of the first reflector member.

16. The solar collector as specified in claim 14 wherein the second reflector member is positioned at a focal point of the first reflector member.

17. The solar collector as specified in claim 14 wherein the second reflector member is positioned after a focal point of the first reflector member.

18. The solar collector as specified in claim 14 wherein the solar receiver is positioned above the parabolic surface.

19. The solar collector as specified in claim 14 wherein the solar receiver is positioned below the parabolic surface.

20. The solar collector as specified in claim 14 wherein the second reflector has multiple sections forming a honeycomb shape geometry.

21. The solar collector as specified in claim 14 wherein the second reflector member is selected from the set of a compound parabolic cone, pyramidal section, sectional cone, and hyperbolic trumpet cone.

22. The solar collector as specified in claim 14 further comprising a third reflector member configured to receive the concentrated sunlight from the second reflector member and concentrate the received sunlight to the solar receiver to form a 3-stage concentrator.

23. The solar collector as specified in claim 2 wherein the solar receiver comprises triple junction solar cells.

24. The solar collector as specified in claim 2 wherein each of the plurality of members are semi-rigid or rigid.

25. The solar collector as specified in claim 6 further comprising a cylinder container configured to receive the first reflector member.

26. The solar collector as specified in claim 25 wherein the container is configured to hold fluid for heating and cooling.

27. The solar collector as specified in claim 2 further comprising tracking means for the solar collector to track the sun and adjust azimuth and elevation.

28. The solar collector as specified in claim 27 wherein the tracking means is responsive to a voltage or current generated by a photovoltaic converter comprising the solar receiver.

29. The solar collector as specified in claim 28 wherein the photovoltaic converter comprises of standard 1× or low concentration type photovoltaic cells.

30. The solar collector as specified in claim 2 wherein the reflective surface is formed through a vapor deposition method.

31. The solar collector as specified in claim 2 wherein the reflective surface includes an applied film or sheet.
